(19) United States
(12) Patent Application Publication
(10) Pub. No.: US 2024/0291435 A1
(43) Pub. Date: Aug. 29, 2024

(54) MIXER CIRCUIT

(71) Applicant: Nippon Telegraph and Telephone Corporation, Tokyo (JP)

(72) Inventors: Hiroshi Hamada, Tokyo (JP); Teruo Jo, Tokyo (JP)

(21) Appl. No.: 18/572,596

(22) PCT Filed: Jun. 24, 2021
(86) PCT No.: PCT/JP2021/023952

§ 371 Date: Dec. 20, 2023

(51) Int. Cl. H03D 7/12; H01P 5/12; H03D 7/16; H04B 1/04; H04B 1/30

(52) U.S. Cl. CPC H03D 7/12; H01P 5/12; H04B 1/0458; H03D 7/165; H04B 1/30

(57) ABSTRACT

An embodiment is a mixer circuit including a power divider that divides an LO signal with equal amplitude and equal phase, delay circuits, unit mixers, transmission lines, and a power combiner that combines, with equal amplitude and equal phase, RF signals output from the unit mixers. A phase delay amount of the LO signal by the k-th delay circuit from an IF port side is set to θ₁−kΔθ_{IF} or θ₁+kΔθ_{IF}, where Δθ_{IF} is a phase delay amount with respect to an IF signal of each of the transmission lines.

### CROSS-REFERENCE TO RELATED APPLICATIONS

This application is a national phase entry of PCT Application No. PCT/JP2021/023952, filed on, Jun. 24, 2021, which application is hereby incorporated herein by reference.

### TECHNICAL FIELD

The present disclosure relates to a circuit technology for handling high-frequency electrical signals.

### BACKGROUND

Broadband THz waves (electromagnamaetic waves of 300 GHz to 30 THz) have been considered to be applied to ultra-high-speed wireless communication such as next-generation wireless communication (beyond 5G). In particular, 300 GHz band, among the THz band, is a frequency band in which absorption and attenuation occur less during atmospheric propagation and an electronic device constituted by a complementary metal oxide semiconductor (CMOS), SiGe, InP, and the like can act as a transmitter (TX) and a receiver (RX), and thus research and development have been actively promoted (see, for example, Non Patent Literature 1 and Non Patent Literature 2).

In particular, InP, which has excellent high frequency characteristics, is a semiconductor material that allows for achieving an amplifier having a gain as high as about 20 dB even at 300 GHz, and thus can be said to be a promising material for achieving a high-performance TX and receiver (see, for example, Non Patent Literature 3).

### CITATION LIST

### Non Patent Literature

Non Patent Literature 1: S. Lee et al., “An 80-Gb/s 300-GHz-Band Single-Chip CMOS Transceiver”, IEEE Journal of Solid-State Circuits (JSSC), vol. 54, no. 12, pp. 3577-3588 October 2019
Non Patent Literature 2: P. Rodriguez-Vazquez et al., “A 16-QAM 100-Gb/s 1-M wireless link with an EVM of 17% at 230 GHz in an SiGe technology”, IEEE Microwave and Wireless Components Letters (MWCL), vol. 29, no. 4, pp. 297-299, April 2019
Non Patent Literature 3: H. Hamada et al., “300-GHz-band 120-Gb/s Wireless Front-End Based on InP-HEMT PAs and Mixers”, IEEE Journal of Solid-State Circuits (JSSC), vol. 55, no. 9, 2020

### SUMMARY

### Technical Problem

The embodiments of the present invention has been made to solve the above problems, and an object thereof is to increase the linearity of a mixer circuit.

### Solution to Problem

The embodiments of the present invention provides a mixer circuit including: a power divider configured to divide an LO signal into N (N is an integer of 2 or more) with equal amplitude and equal phase; N transmission lines that are connected in series between an IF port to which an IF signal is input and ground; N unit mixers that have IF signal input terminals connected to corresponding terminations of the N transmission lines; N delay circuits that are individually inserted between N output terminals of the power divider and LO signal input terminals of the N unit mixers; and a power combiner configured to combine, with equal amplitude and equal phase, N RF signals output from the N unit mixers, in which a phase delay amount of the LO signal by a k-th (k is an integer of 1 to N) delay circuit from the IF port side among the delay circuits is set to θ1−kΔθIF or θ1+kΔθIF (θ1 is an optional phase), where ΔθIF is a phase delay amount with respect to an IF signal of each of the N transmission lines.

Furthermore, a configuration example of the present invention provides the mixer circuit further including: N first amplifiers that are individually inserted between the N output terminals of the power divider and input terminals of the N delay circuits; and N second amplifiers that are individually inserted between output terminals of the N delay circuits and the LO signal input terminals of the N unit mixers.

Furthermore, a configuration example of the present invention provides the mixer circuit further including: third amplifiers that are individually inserted between RF signal output terminals of the N unit mixers and N input terminals of the power combiner.

Furthermore, embodiments of the present invention provides a mixer circuit including: a first power divider configured to divide an LO signal into N (N is an integer of 2 or more) with equal amplitude and equal phase; a second power divider configured to divide an RF signal into N with equal amplitude and equal phase; N transmission lines that are connected in series between an IF port from which an IF signal is output and ground; N unit mixers that have RF signal input terminals connected to corresponding N output terminals of the second power divider and IF signal output terminals connected to corresponding terminations of the N transmission lines; and N delay circuits that are individually inserted between N output terminals of the first power divider and LO signal input terminals of the N unit mixers, in which a phase delay amount of the LO signal by a k-th (k is an integer of 1 to N) delay circuit from the IF port side among the delay circuits is set to θ1−(N−k+1)ΔθIF or θ1+(N−k+1)ΔθIF (θ1 is an optional phase), where ΔθIF is a phase delay amount with respect to an IF signal of each of the N transmission lines.

Furthermore, a configuration example of the present invention provides the mixer circuit further including: N first amplifiers that are individually inserted between the N output terminals of the first power divider and input terminals of the N delay circuits; and N second amplifiers that are individually inserted between output terminals of the N delay circuits and the LO signal input terminals of the N unit mixers.

Furthermore, a configuration example of the present invention provides the mixer circuit further including: N third amplifiers that are individually inserted between the N output terminals of the second power divider and the RF signal input terminals of the N unit mixers.

Furthermore, embodiments of the present invention provides a mixer circuit including: a power divider configured to divide an LO signal into N (N is an integer of 2 or more) with equal amplitude and equal phase; N transistors that have sources connected to ground; N delay circuits that are individually inserted between N output terminals of the power divider and gates of the N transistors; a power combiner configured to combine, with equal amplitude and equal phase, N RF signals output from drains of the N transistors; 2N first transmission lines that are connected in series between an IF port to which an IF signal is input and ground; N second transmission lines, each of the N second transmission lines being inserted between a gate of a k-th transistor from the IF port side among the transistors and a connection point between a (2k−1)th (k is an integer of 1 to N) first transmission line and a 2k-th first transmission line from the IF port side among the first transmission lines, and having a length of quarter wavelength at a frequency of the LO signal; and N third transmission lines, each of the N third transmission lines having one end connected to a connection point between the (2k−1)th first transmission line and the 2k-th first transmission line, having the other end opened, and having a length of quarter wavelength at the frequency of the LO signal, in which a phase delay amount of the LO signal by a k-th delay circuit from the IF port side among the delay circuits is set to θ1−kΔθIF or θ1+kΔθIF (θ1 is an optional phase), where ΔθIF is a total phase delay amount of the (2k−1)th first transmission line and the 2k-th first transmission line with respect to an IF signal.

Furthermore, embodiments of the present invention provides a mixer circuit including: a power divider configured to divide an LO signal into N (N is an integer of 2 or more) with equal amplitude and equal phase; N transistors that have sources connected to ground; N delay circuits that are individually inserted between N output terminals of the power divider and gates of the N transistors; a power combiner configured to combine, with equal amplitude and equal phase, N RF signals output from drains of the N transistors; 2N+1 first transmission lines that are connected in series between an IF port to which an IF signal is input and the ground, and have a length of quarter wavelength at a frequency of the RF signals; N+1 second transmission lines, each of the N+1 second transmission lines being inserted between a termination of a (2k−1)th (k is an integer of 1 to N) first transmission line from the IF port side among the first transmission lines and an input end of a 2k-th first transmission line among the first transmission lines, and between a termination of a (2N+1)th first transmission line among the first transmission lines and the ground; N+1 third transmission lines, each of the N+1 third transmission lines having one end connected to a connection point between a (2i−1)th (i is an integer of 1 to N+1) first transmission line from the IF port side among the first transmission lines and an i-th second transmission line among the second transmission lines, having the other end opened, and having a length of quarter wavelength at the frequency of the RF signals; and N fourth transmission lines, each of the N fourth transmission lines having one end connected to a connection point between the 2k-th first transmission line from the IF port side among the first transmission lines and a k-th second transmission line among the second transmission lines, having the other end opened, and having a length of quarter wavelength at the frequency of the RF signals, in which a phase delay amount of the LO signal by a k-th delay circuit from the IF port side among the delay circuits is set to θ1−kΔθIF or θ1+kΔθIF (θ1 is an optional phase), where ΔθIF is a total phase delay amount of the (2k−1)th first transmission line, the 2k-th first transmission line, and the k-th second transmission line with respect to an IF signal.

### Advantageous Effects of Embodiments of the Invention

According to embodiments of the present invention, by setting a phase delay amount of the LO signal by a delay circuit so as to enable power combining, the linearity of the mixer circuit can be increased N-fold of that of each unit mixer.

### BRIEF DESCRIPTION OF THE DRAWINGS

FIG. 1 is a block diagram illustrating a configuration of a mixer circuit according to a first embodiment of the present invention.

FIG. 2 is a block diagram illustrating a configuration of a general distribution mixer.

FIG. 3 is a block diagram illustrating another configuration of the mixer circuit according to the first embodiment of the present invention.

FIG. 4 is a block diagram illustrating a configuration of a mixer circuit according to a second embodiment of the present invention.

FIG. 5 is a block diagram illustrating another configuration of the mixer circuit according to the second embodiment of the present invention.

FIG. 6 is a block diagram illustrating a configuration of a mixer circuit according to a third embodiment of the present invention.

FIG. 7 is a block diagram illustrating another configuration of the mixer circuit according to the third embodiment of the present invention.

FIG. 8 is a block diagram illustrating a configuration of a mixer circuit according to a fourth embodiment of the present invention.

FIG. 9 is a diagram illustrating an outline of a gate mixer.

FIG. 10 is a block diagram illustrating a configuration of a mixer circuit according to a fifth embodiment of the present invention.

FIG. 11 is a diagram illustrating an outline of a resistive mixer.

FIG. 12 is a block diagram illustrating a configuration of a mixer circuit according to a sixth embodiment of the present invention.

FIG. 13 is a block diagram illustrating a configuration of a conventional transmitter.

FIG. 14 is a block diagram illustrating a configuration of a power amplifier using a power combining technology.

FIG. 15 is a block diagram illustrating a configuration of a mixer using the power combining technology.

### DETAILED DESCRIPTION OF ILLUSTRATIVE EMBODIMENTS

The present disclosure relates to a circuit technology for handling high-frequency electrical signals, and particularly to a mixer circuit having a frequency conversion function.

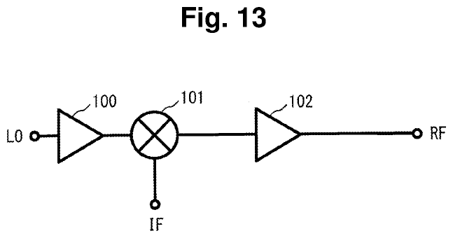

FIG. 13 illustrates a configuration of a general TX. The TX includes an amplifier 100, a mixer 101, and a power amplifier (PA) 102. The mixer 101 generates a radio frequency (RF) signal of a desired frequency band by multiplying an intermediate frequency (IF) signal by a local oscillator (LO) signal. The PA 102 power-amplifies and outputs the RF signal.

It is important for the TX to increase output power to extend the distance of wireless communication and secure a signal to noise ratio (SNR) of communication. Furthermore, considering a case of performing multilevel modulation such as quadrature amplitude modulation (QAM), linearity for amplifying an RF signal output from the mixer without distortion is important. As indices of linearity, a 1 dB gain suppression point output (OP1dB), which is an output at a point where the gain decreases by 1 dB from a small-signal gain, and a 1 dB gain suppression point input (IP1dB), which is an input at a point where the gain decreases by 1 dB from the small-signal gain, are used.

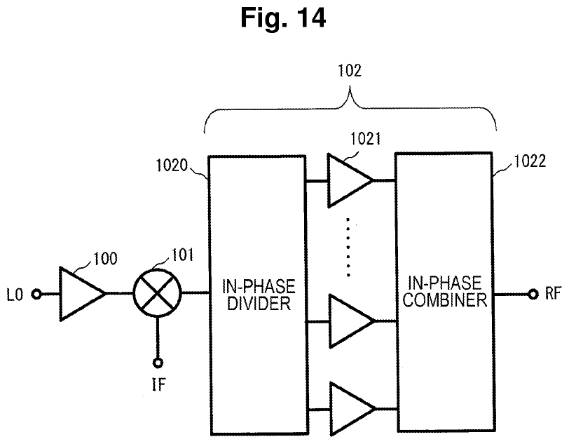

In order to increase the linearity, a power combining technology using an in-phase divider 1020, a plurality of amplifiers 1021, and an in-phase combiner 1022 is generally used in the PA 102 as illustrated in FIG. 14. In a case where the power combining technology is used, assuming that each of the amplifiers 1021 that are targets of power combining has the same performance, the OP1dB can be ideally increased N-fold, where N (N=1, 2, . . . ) is the number of times of power combining. Thus, increasing the linearity of a PA has been established by a conventional technology.

Next, it will be described below that increasing the linearity of not only the PA but also the mixer is important in the ultra-high frequency band such as the 300 GHz band.

In an extremely high frequency band such as the 300 GHz band, the gain per transistor is small, and this makes it difficult to provide a large gain for the PA as in a low frequency band. The gain of a PA in the 300 GHz band is typically about 10 dB.

For a similar reason, it is difficult to provide a large conversion gain (ratio of an output RF signal to an input IF signal) for a mixer. A typical conversion gain in the 300 GHz band is about −20 dB. Therefore, the conversion gain of a typical TX is only about −20+10=−10 dB. In a case where it is desired to obtain an RF linear output signal of 0 dBm from a TX with a conversion gain of −10 dB, it is necessary to set the IF signal input to the mixer to a value as high as 10 dBm. The mixer therefore needs to secure linearity for an input IF signal of 10 dBm. The IP1dB of a mixer is normally 0 dBm or less. It is therefore difficult to secure linearity for an input IF signal of 10 dBm.

The gain of a PA in a frequency band of 100 GHz or less is typically 20 dB, and the conversion gain of a mixer is typically −10 dB. In a case where the gain of the PA is 20 dB and the conversion gain of the mixer is −10 dB, the conversion gain of the TX is 20−10=10 dB. Thus, in a case where it is desired to obtain an RF linear output signal of 0 dBm from the TX, the IF signal input to the mixer only needs to be a small signal of −10 dBm. Thus, the mixer only needs to ensure linearity for a signal of at most-10 dBm. This performance is a value that can be sufficiently achieved with a typical mixer of a normal type.

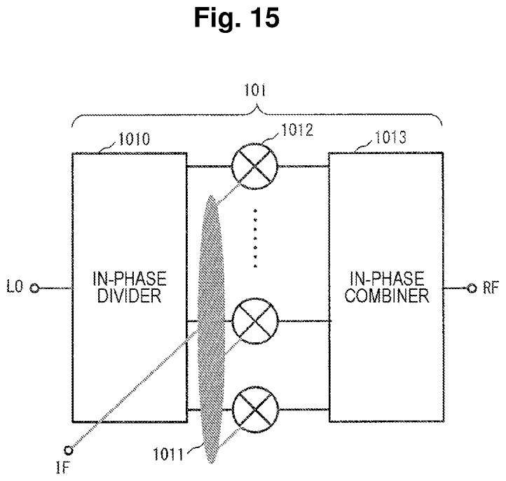

It can be seen from the above that increasing the linearity of the mixer is important in the 300 GHz band in which the gains of the PA and the mixer decrease. The linearity of the mixer 101 illustrated in FIG. 13 can also be increased in principle with the use of the power combining technology. For example, the mixer 101 in FIG. 15 includes an in-phase divider 1010 for LO signals, an in-phase divider 1011 for IF signals, a plurality of mixers 1012, and an in-phase combiner 1013. That is, by arranging N mixers 1012 having the same performance in parallel and performing power combining on each of the LO signals, the IF signals, and the RF signals of the individual mixers 1012, it is possible to increase the linearity N-fold.

However, it is difficult to achieve the configuration illustrated in FIG. 15 by an integrated circuit technology using a transistor and the like. Specifically, it is difficult to achieve the in-phase divider 1011 for IF signals arranged in a direction intersecting a path for LO signals and a path for RF signals with the use of an integrated circuit technology of forming a circuit on a plane. This difficulty results from the fact that the mixers 1012 are 3-port elements, not 2-port elements as in the PA.

As described above, it is important to increase the linearity of the mixers at a high frequency such as 300 GHz, but the mixers are 3-port elements, and this has posed a problem in that it is difficult to increase the linearity of the mixers by power combining.

### First Embodiment

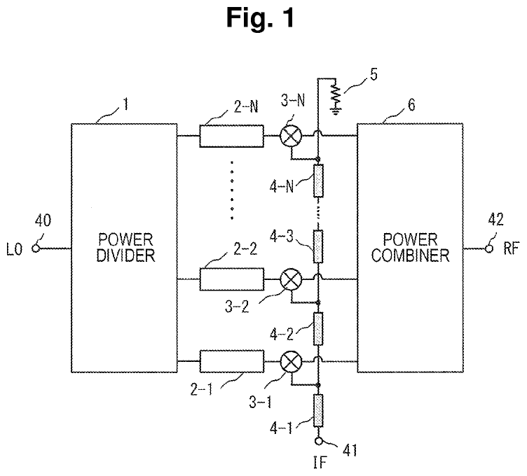

Hereinafter, embodiments of the present invention will be described with reference to the drawings. FIG. 1 is a block diagram illustrating a configuration of a mixer circuit according to the present embodiment. The mixer circuit includes a power divider 1 that divides an LO signal into N (N is an integer of 2 or more) with equal amplitude and equal phase, N delay circuits 2-1 to 2-N, N unit mixers 3-1 to 3-N, N transmission lines 4-1 to 4-N that are connected in series between ground and an IF port 41 to which IF signals are input and have individual terminations connected to IF signal input terminals of the unit mixers 3-1 to 3-N, a termination resistor 5 that connects the ground and the termination of the transmission line 4-N in the final stage, and a power combiner 6 that combines, with equal amplitude and equal phase, N RF signals output from the unit mixers 3-1 to 3-N. Reference numeral 40 denotes an LO port to which LO signals are input, and reference numeral 42 denotes an RF port from which RF signals are output.

In the present embodiment, a distribution matching technology is used to achieve power combining of IF signals in a planar circuit. The distribution matching technology is a technique for achieving broadband impedance matching by forming an N-stage ladder-type pseudo transmission line constituted by an inductance of each of the N transmission lines 4-1 to 4-N arranged and a parasitic capacitance of each of the N unit mixers 3-1 to 3-N arranged in a similar manner.

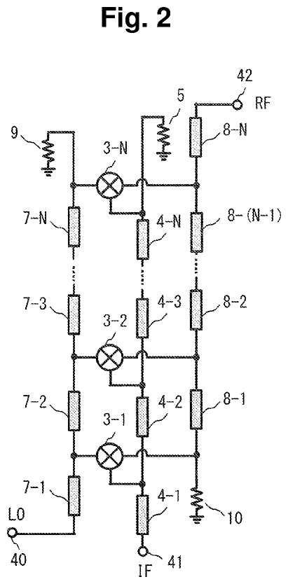

Mixer circuits subjected to distribution matching are generally referred to as distribution mixers. In a distribution mixer, a distribution matching circuit is normally formed for each of IF signals, LO signals, and RF signals. FIG. 2 illustrates a configuration of a general distribution mixer. Reference numerals 7-1 to 7-N and 8-1 to 8-N denote transmission lines, and reference numerals 9 and 10 denote termination resistors.

Distribution mixers allow for securing a wide band for IF signals, LO signals, and RF signals, but it is not possible to increase the linearity N-fold by designing a distribution mixer in which the N unit mixers 3-1 to 3-N are arranged. The reason why the linearity cannot be increased N-fold is due to distribution matching for LO signals. That is, in the configuration in FIG. 2, an input LO signal attenuates while propagating through the transmission lines 7-1 to 7-N, and the power of the LO signal that drives the first unit mixer 3-1 from the IF port 41 side and the power of the LO signal that drives the N-th unit mixer 3-N are greatly different.

In general, in the unit mixers 3-1 to 3-N, there is a positive correlation between the power of the LO signal and the linearity. In order to secure linearity of the mixer circuit, it is necessary to supply sufficient power of the LO signal to the unit mixers 3-1 to 3-N. However, it is difficult to supply sufficient power of the LO signal to all of the N unit mixers 3-1 to 3-N due to loss in the transmission lines 7-1 to 7-N described above. That is, each of the N unit mixers 3-1 to 3-N has a different linearity (IP1dB). Therefore, the overall linearity of the distribution mixer using the N unit mixers 3-1 to 3-N is not increased N-fold of that in a case where one unit mixer is used.

In general, the linearity of the distribution mixer is approximately equal to or slightly larger than the linearity of the first unit mixer 3-1 to which the largest LO signal is supplied. In addition, since the loss with respect to an RF signal due to an RF distribution matching circuit constituted by the transmission lines 8-1 to 8-N and the termination resistor 10 is also large, the conversion gain and the OP1dB of the distribution mixer are usually smaller than those in a case where one unit mixer is used.

Thus, in the present embodiment, an IF distribution matching circuit constituted by the transmission lines 4-1 to 4-N and the termination resistor 5 is used for IF signals as illustrated in FIG. 1, but distribution matching circuits are not used for LO signals and RF signals. The reason why an LO distribution matching circuit and an RF distribution matching circuit are not used is to supply LO signals of the same power to all the unit mixers 3-1 to 3-N.

However, not using an LO distribution matching circuit and an RF distribution matching circuit causes a problem in phase matching of the mixer. All of the RF signals, LO signals, and IF signals are phase matched in the distribution mixer illustrated in FIG. 2, but there is a possibility that the signals are not phase matched in the configuration of the present embodiment illustrated in FIG. 1. That is, there is a possibility that the phases of the RF signals output from the unit mixers 3-1 to 3-N vary, and using the power combiner 6 with N input and 1 output does not allow for achieving N-fold power combining.

In the present embodiment, in order to make RF signals output from the individual unit mixers 3-1 to 3-N to be in the same phase, the delay circuits 2-1 to 2-N are applied to N LO signals divided by the power divider 1 as illustrated in FIG. 1. The delay circuits 2-1 to 2-N are individually inserted between N output terminals of the power divider 1 and LO signal input terminals of the N unit mixers 3-1 to 3-N. The delay circuits 2-1 to 2-N can be constituted by transmission lines or the like.

In multiplication of an LO signal and an IF signal in a unit mixer, a phase ORF of an RF signal is generally expressed as follows.

$$θRF = θ LO + θIF \qquad ( 1 )$$

$$θRF = θ LO - θIF \qquad ( 2 )$$

Formula (1) shows a case where the frequency of an RF signal is equal to the sum of the frequency of an LO signal and the frequency of an IF signal, that is, a case where an upper side band is used as RF signals. Formula (2) shows a case where the frequency of an RF signal is equal to the difference between the frequency of an LO signal and the frequency of an IF signal, that is, a case where a lower side band is used as RF signals.

Therefore, in a case where the upper side band is used as RF signals, by setting, to θ1−kΔθIF, the phase delay amount of the LO signal by the k-th (k is an integer of 1 to N) delay circuit 2-k from the IF port 41 side, it is possible to make all the phases of the RF signals output from the N unit mixers 3-1 to 3-N to have the same value θ1 (θ1 is an optional phase). The phase delay amount with respect to an IF signal of each of the transmission lines 4-1 to 4-N is set to the same value ΔθIF.

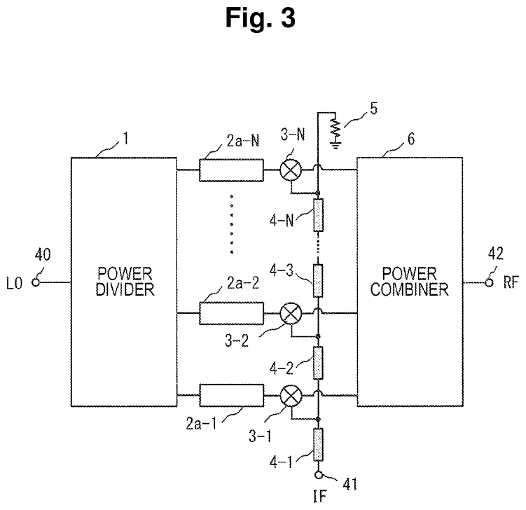

FIG. 3 illustrates a configuration of the mixer circuit of the present embodiment in which the lower side band is used as RF signals. In a case where the lower side band is used as RF signals, by setting, to θ1+kΔθIF, the phase delay amount of the LO signal by a k-th delay circuit 2a-k from the IF port 41 side, it is possible to make all the phases of the RF signals output from the N unit mixers 3-1 to 3-N to have the same value θ1.

In general, in a case of a mixer circuit in the 300 GHz band, the frequency of the LO signals is 250 GHz or more, and the frequency of the IF signals is about 25 GHZ, that is, there is about 10 times difference in frequency between the LO signals and the IF signals. The length of the delay circuits 2-1 to 2-N and delay circuits 2a-1 to 2a-N necessary for obtaining the same phase delay amount as the IF signals is only 1/10 of the length of the transmission lines for IF signals. Great differences from the distribution mixer in FIG. 2 include that the delay circuits 2-1 to 2-N and 2a-1 to 2a-N for LO signals are short in length.

In the distribution mixer illustrated in FIG. 2, the transmission lines 4-1 to 4-N, 7-1 to 7-N, and 8-1 to 8-N for IF signals, LO signals, and RF signals normally have substantially the same physical length. Thus, in cases of LO signals and RF signals having high frequencies, the loss inevitably becomes larger. In the present embodiment, the delay circuits 2-1 to 2-N and 2a-1 to 2a-N for LO signals are short, and the loss due to the delay circuits 2-1 to 2-N and 2a-1 to 2a-N does not cause any problem.

In designing the IF distribution matching circuit constituted by the transmission lines 4-1 to 4-N and the termination resistor 5, physical parameters (width and length) of the transmission lines 4-1 to 4-N may be determined such that a characteristic impedance of a pseudo transmission line constituted by capacitances of the unit mixers 3-1 to 3-N and the inductances of the transmission lines 4-1 to 4-N becomes a desired value (normally 50Ω).

When the physical parameters of the transmission lines 4-1 to 4-N have been determined, the phase delay amount ΔθIF of each of the transmission lines 4-1 to 4-N is determined accordingly, and thus it is possible to determine physical parameters of the delay circuits 2-1 to 2-N and 2a-1 to 2a-N for LO signals. In addition, due to the principle of distribution matching, arranging a resistor of 50Ω as the termination resistor 5 at the termination of the IF port 41 allows for obtaining a broadband mixer characteristic.

As described above, the present embodiment provides a configuration in which the N unit mixers 3-1 to 3-N are driven by LO signals of the same power and RF signals of the same phase are output, and this allows the linearity of the mixer circuit to be increased N-fold of that of each unit mixer.

### Second Embodiment

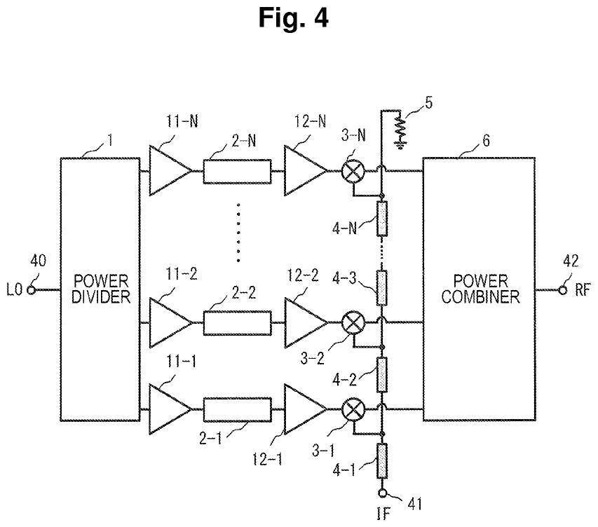

In the first embodiment, it is possible that the overall operation of the mixer circuit is affected by a slight loss due to the delay circuits 2-1 to 2-N and 2a-1 to 2a-N and a change in impedance seen from the unit mixers 3-1 to 3-N to the LO signal side, and a more practical configuration is illustrated in FIG. 4.

A mixer circuit of the present embodiment is obtained by, in the mixer circuit of the first embodiment, inserting amplifiers 11-1 to 11-N for amplifying LO signals individually between the N output terminals of the power divider 1 and input terminals of the N delay circuits 2-1 to 2-N, and inserting amplifiers 12-1 to 12-N for amplifying LO signals individually between output terminals of the N delay circuits 2-1 to 2-N and the LO signal input terminals of the N unit mixers 3-1 to 3-N.

By designing each of the amplifiers 11-1 to 11-N and 12-1 to 12-N to perform saturation operation, it is possible to drive the N unit mixers 3-1 to 3-N with LO signals of completely the same power (saturation power of the amplifiers 11-1 to 11-N and 12-1 to 12-N) even in a case where there is some variation in the loss in the delay circuits 2-1 to 2-N. In addition, the amplifiers 11-1 to 11-N and 12-1 to 12-N generally have reverse isolation. Thus, the impedance as seen from the unit mixers 3-1 to 3-N is not affected by the delay circuits 2-1 to 2-N.

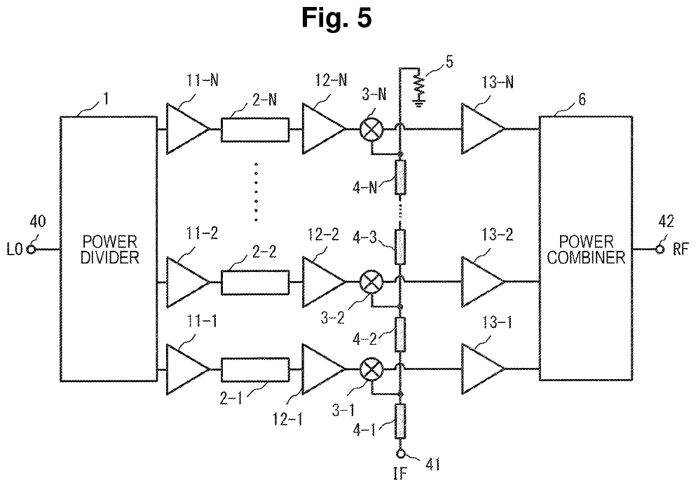

Furthermore, by inserting amplifiers 13-1 to 13-N for amplifying RF signals individually between RF signal output terminals of the N unit mixers 3-1 to 3-N and N input terminals of a power combiner 6 as illustrated in FIG. 5, it is possible to amplify outputs of the unit mixers 3-1 to 3-N without being affected by excessive loss in the power combiner 6, and the conversion gain of the mixer circuit of the present embodiment can be further improved.

While the delay circuits 2-1 to 2-N are used in the examples in FIGS. 4 and 5, it is possible to provide delay circuits 2a-1 to 2a-N instead of the delay circuits 2-1 to 2-N in FIGS. 4 and 5 to achieve a configuration in which the lower side band is used as RF signals.

Furthermore, side benefits of embodiments of the present invention include an image rejection function. In general, only either the upper side band or the lower side band is used as RF signals in wireless communication. The reason for using only either the upper side band or the lower side band is to effectively utilize the bands and to improve the SNR.

For example, in a case where the upper side band is used for RF signals, the lower side band is treated as spurious signals called image signals. It is therefore desirable for a TX to have a function of rejecting image signals in some cases. Mixers having a function of rejecting image signals are generally referred to as image rejection mixers.

In embodiments of the present invention, the design of the delay circuits 2-1 to 2-N in a case where the upper side band is used for RF signals and the design of the delay circuits 2a-1 to 2a-N in a case where the lower side band is used for RF signals are different. The delay circuits 2-1 to 2-N and 2a-1 to 2a-N are designed so that the phases in either the upper side band or the lower side band are the same in the outputs of the N unit mixers 3-1 to 3-N. This is because the power combiner 6 cannot combine the powers of N RF signals unless the unit mixers 3-1 to 3-N are designed to output the same phase.

In other words, as for image signals, the unit mixers 3-1 to 3-N output different phases. Thus, the power combiner 6 cannot efficiently combine the powers, and the conversion gain for an image signal becomes lower than the conversion gain for an RF signal. Therefore, the mixer circuit of embodiments of the present invention essentially has an image rejection function.

### Third Embodiment

While the first and second embodiments take an example of an up-conversion mixer used for a TX, embodiments of the present invention can also be applied to a down-conversion mixer used for an RX. However, also in this case, it is necessary to appropriately design the delay amount of an LO signal.

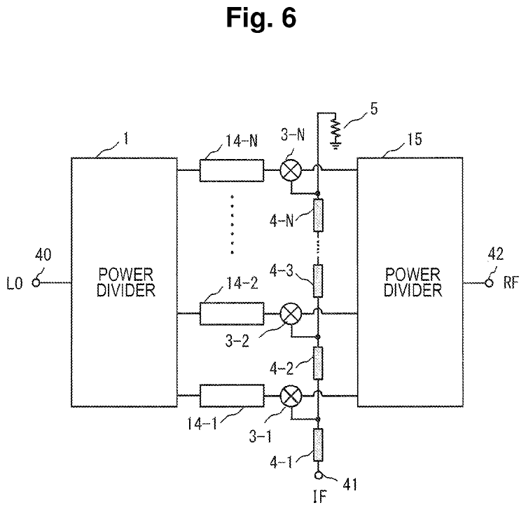

FIG. 6 is a block diagram illustrating a configuration of a mixer circuit according to the present embodiment. The mixer circuit of the present embodiment includes a power divider 1, unit mixers 3-1 to 3-N, transmission lines 4-1 to 4-N, a termination resistor 5, N delay circuits 14-1 to 14-N individually inserted between N output terminals of the power divider 1 and LO signal input terminals of the N unit mixers 3-1 to 3-N, and a power divider 15 that divides RF signals with equal amplitude and equal phase and inputs the RF signals to RF signal input terminals of the N unit mixers 3-1 to 3-N. Since the mixer circuit of the present embodiment is a down-conversion mixer, an IF port 41 is a port that outputs IF signals, and an RF port 42 is a port to which RF signals are input.

In a case where the upper side band is used as RF signals, the phase delay amount of the LO signal by the k-th (k is an integer of 1 to N) delay circuit 14-k from the IF port 41 side is set to θ1−(N−k+1)ΔθIF. The phase of the LO signal input to the k-th unit mixer 3-k is θ1−(N−k+1)ΔθIF. The phase of the RF signal input to the k-th unit mixer 3-k is ORF. ORF is a fixed value that does not depend on k.

The phase of the IF signal output from the k-th unit mixer 3-k is θRF−[θ1−(N−k+1)ΔθIF]. The phase of the IF signal output from the k-th unit mixer 3-k at the IF port 41 is θRF−[θ1-(N−k+1)+ΔθIF]+kΔIF=θRF−[θ1−(N+1)ΔθIF], since the IF signal passes through k transmission lines 4-k to 4-1. That is, the phase of the IF signal at the IF port 41 does not depend on k. Therefore, the IF signals output from the N unit mixers 3-1 to 3-N are subjected to in-phase combining at the IF port 41.

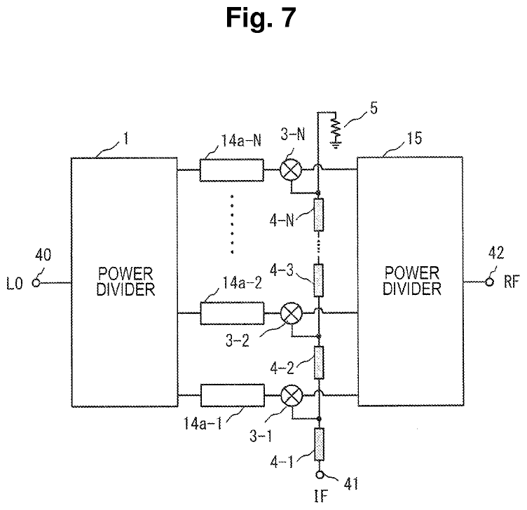

FIG. 7 illustrates a configuration of the mixer circuit of the present embodiment in which the lower side band is used as RF signals. In a case where the lower side band is used as RF signals, the phase delay amount of the LO signal by a k-th delay circuit 14a-k from the IF port 41 side may be set to θ1+(N−k+1)ΔθIF.

### Fourth Embodiment

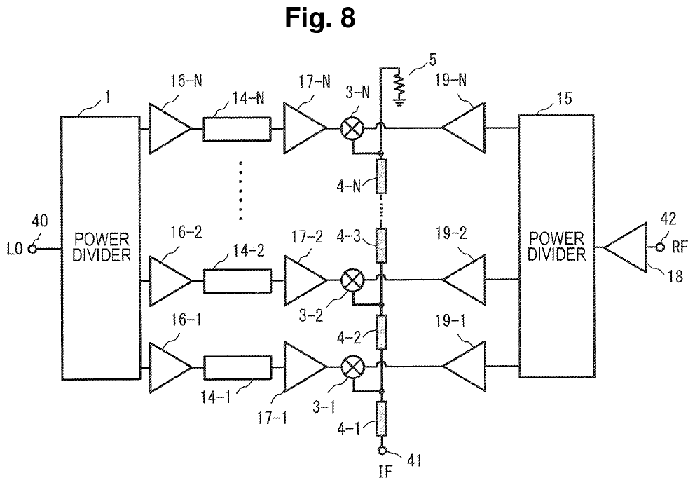

A configuration more practical than that of the third embodiment is illustrated in FIG. 8. A mixer circuit of the present embodiment is obtained by, in the mixer circuit of the third embodiment, inserting amplifiers 16-1 to 16-N for amplifying LO signals individually between the N output terminals of the power divider 1 and input terminals of the N delay circuits 14-1 to 14-N, and inserting amplifiers 17-1 to 17-N for amplifying LO signals individually between output terminals of the N delay circuits 14-1 to 14-N and the LO signal input terminals of the N unit mixers 3-1 to 3-N. Furthermore, in the present embodiment, a pre-amplifier 18 for amplifying RF signals is inserted between an RF port 42 and an input terminal of a power divider 15, and amplifiers 19-1 to 19-N for amplifying the RF signals are individually inserted between N output terminals of the power divider 15 and RF signal input terminals of the N unit mixers 3-1 to 3-N.

In an RX, RF loss in the first stage greatly affects a noise figure (NF). Thus, in order to avoid NF degradation due to the loss in the power divider 15, the pre-amplifier 18 is provided in the stage preceding the power divider 15 in FIG. 8.

While the delay circuits 14-1 to 14-N are used in the example in FIG. 8, it is possible to provide delay circuits 14a-1 to 14a-N instead of the delay circuits 14-1 to 14-N in FIG. 8 to achieve a configuration in which the lower side band is used as RF signals.

### Fifth Embodiment

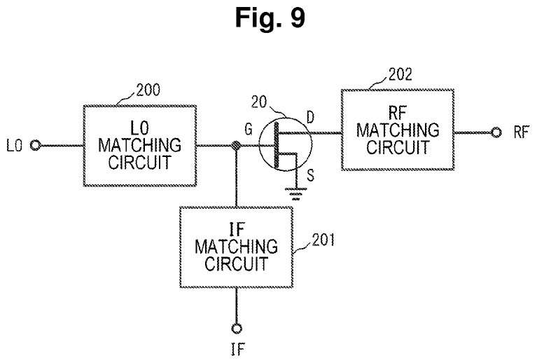

Next, a fifth embodiment of the present invention will be described. In the present embodiment, a case where a gate mixer is used as a unit mixer will be described. As illustrated in FIG. 9, the gate mixer inputs an IF signal and an LO signal to a gate G of a common-source field effect transistor (FET) 20, and extracts an RF signal from a drain D of the FET 20.

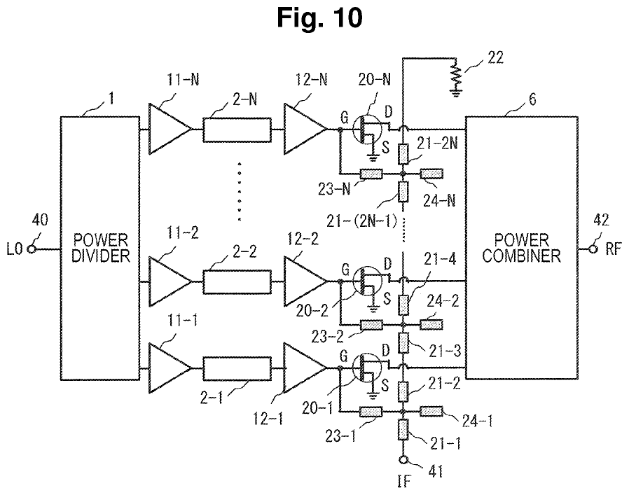

FIG. 10 is a block diagram illustrating a configuration of a mixer circuit according to the present embodiment. The mixer circuit of the present embodiment includes: a power divider 1; delay circuits 2-1 to 2-N; a power combiner 6; amplifiers 11-1 to 11-N and 12-1 to 12-N; N FETs 20-1 to 20-N having gates G connected to output terminals of the amplifiers 12-1 to 12-N, drains D connected to input terminals of the power combiner 6, and sources S connected to ground; 2N transmission lines 21-1 to 21-2N connected in series between an IF port 41 and ground; a termination resistor 22 of 50Ω that connects a termination of the transmission line 21-2N and the ground; N transmission lines 23-1 to 23-N, each of the N transmission lines 23-1 to 23-N being inserted between the gate G of the k-th (k is an integer of 1 to N) FET 20-k and a connection point between the (2k−1)th (k is an integer of 1 to N) transmission line 21-(2k−1) and the 2k-th transmission line 21-2k from the IF port 41 side, and having a length of quarter wavelength at the frequency of the LO signal; and N transmission lines 24-1 to 24-N, each of the N transmission lines 24-1 to 24-N having one end connected to a connection point between the transmission line 21-(2k−1) and the transmission line 21-2k, having the other end opened, and having a length of quarter wavelength at the frequency of the LO signal.

The phase delay amounts with respect to an IF signal of the individual transmission lines 21-1 to 21-2N constituting an IF distribution matching circuit are all set to the same value. Then, the total phase delay amount with respect to the IF signal of the two adjacent transmission lines 21-(2k−1) and 21-2k is set to ΔΘIF.

The gate mixer in FIG. 9 allows for up-conversion from an IF signal into an RF signal, but does not allow for down-conversion from an RF signal into an IF signal. Therefore, the mixer circuit of the present embodiment naturally acts as an up-conversion mixer.

With the configuration of the present embodiment, it is possible to obtain high linear characteristics in which the linearity of a normal gate mixer is increased N-fold.

A point to be noted here is isolation between the LO signals and the IF signals. In the lumped constant gate mixer illustrated in FIG. 9, isolation between the LO signals and the IF signals can be achieved by an LO matching circuit 200 and an IF matching circuit 201. However, in the present embodiment, the IF distribution matching circuit constituted by the transmission lines 21-1 to 21-2N and the termination resistor 22 is used, and it is therefore necessary to secure isolation by a technique different from the lumped constant gate mixer.

Thus, in the present embodiment, the transmission lines 23-1 to 23-N and 24-1 to 24-N are used. The transmission lines 24-1 to 24-N are open stubs. Therefore, the impedance at the connection points between the IF distribution matching circuit and the transmission lines 24-1 to 24-N (the connection point between the transmission line 21-(2k−1) and the transmission line 21-2k) is 0 (short circuit) at the frequency of the LO signals.

The transmission lines 23-1 to 23-N rotate signal phases at the connection points between the IF distribution matching circuit and the transmission lines 24-1 to 24-N, and thus the impedance seen from the gates G of the FETs 20-1 to 20-N to the IF distribution matching circuit at the frequency of the LO signals can be made infinite (opened).

As described above, there is about 10 times difference in frequency between the LO signals and the IF signals in the 300 GHz band, and the transmission lines 23-1 to 23-N and 24-1 to 24-N are sufficiently short for the IF signals. Thus, it may be considered that the transmission lines 23-1 to 23-N and 24-1 to 24-N do not adversely affect the characteristics of the IF distribution matching circuit.

As described above, the present embodiment allows for securing isolation between the LO signals and the IF signals in a case where a gate mixer is used as a unit mixer.

In the present embodiment, the amplifiers 11-1 to 11-N and 12-1 to 12-N are not essential components, and as in the first embodiment, N output terminals of the power divider 1 and input terminals of the N delay circuits 2-1 to 2-N may be connected, and output terminals of the N delay circuits 2-1 to 2-N and the gates G of the N FETs 20-1 to 20-N may be connected.

In addition, as in the second embodiment, amplifiers for amplifying RF signals may be individually inserted between the drains D of the N FETs 20-1 to 20-N and N input terminals of the power combiner 6.

While the configuration in FIG. 10 illustrates a case where the upper side band is used as RF signals, in a case where the lower side band is used as RF signals, delay circuits 2a-1 to 2a-N may be provided instead of the delay circuits 2-1 to 2-N.

### Sixth Embodiment

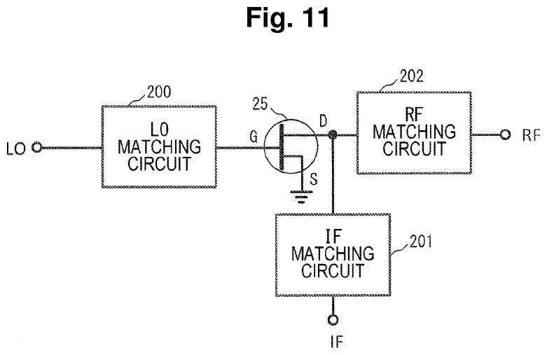

Next, a sixth embodiment of the present invention will be described. In the present embodiment, a case where a resistive mixer is used as a unit mixer will be described. As illustrated in FIG. 11, the resistive mixer has a configuration in which an LO signal is input to a gate G of a common-source FET 25, an IF signal is input to a drain D of the FET 25, and then an RF signal is extracted from the drain D, or an RF signal is input to the drain D and an IF signal is extracted from the drain D.

The resistive mixer in FIG. 11 allows for both up-conversion and down-conversion. Therefore, both an up-conversion mixer and a down-conversion can be achieved in the present embodiment.

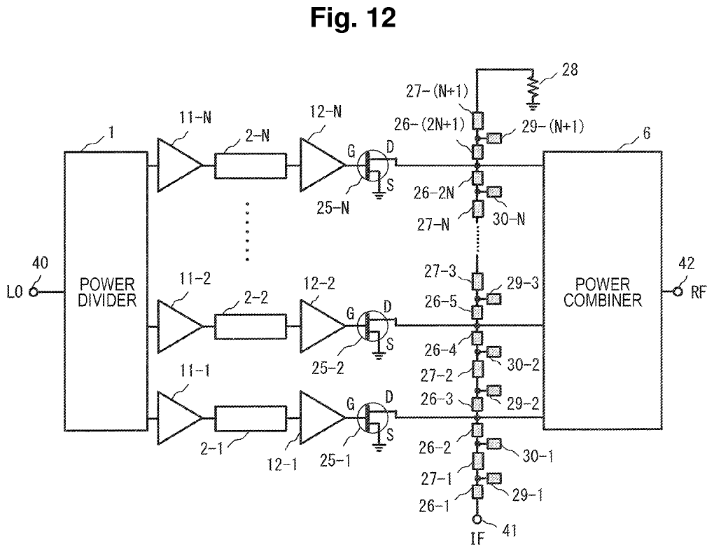

FIG. 12 is a block diagram illustrating a configuration of a mixer circuit according to the present embodiment. The mixer circuit of the present embodiment includes: a power divider 1; delay circuits 2-1 to 2-N; a power combiner 6; amplifiers 11-1 to 11-N and 12-1 to 12-N; N FETs 25-1 to 25-N having gates G connected to output terminals of the amplifiers 12-1 to 12-N, drains D connected to input terminals of the power combiner 6, and sources S connected to ground; 2N+1 transmission lines 26-1 to 26-(2N+1) that are connected in series between an IF port 41 and ground and have a length of quarter wavelength at the frequency of an RF signal; N+1 transmission lines 27-1 to 27-(N+1) inserted between the (2k−1)th (k is an integer of 1 to N) transmission line 26-(2k−1) and the 2k-th transmission line 26-2k from the IF port 41 side, and between the (2N+1)th transmission line 26-(2N+1) and the ground; a termination resistor 28 that connects a termination of the transmission line 27-(N+1) and the ground; N+1 transmission lines 29-1 to 29-(N+1), each of the N+1 transmission lines 29-1 to 29-(N+1) having one end connected to a connection point between the (2i−1)th (i is an integer of 1 to N+1) transmission line 26-(2i−1) and the i-th transmission line 27-i from the IF port 41 side, having the other end opened, and having a length of quarter wavelength at the frequency of the RF signal; and N transmission lines 30-1 to 30-N, each of the N transmission lines 30-1 to 30-N having one end connected to a connection point between the 2k-th transmission line 26-2k and the k-th transmission line 27-k from the IF port 41 side, having the other end opened, and having a length of quarter wavelength at the frequency of the RF signal.

The phase delay amounts with respect to an IF signal of the individual transmission lines 26-1 to 26-(2N+1) are all set to the same value. Similarly, the phase delay amounts with respect to an IF signal of the individual transmission lines 27-1 to 27-(N+1) are all set to the same value. The total phase delay amount of the three transmission lines 26-(2k−1), 26-2k, and 27-k with respect to an IF signal is set to ΔθIF. The configuration in FIG. 12 illustrates an example of an up-conversion mixer.

With the configuration of the present embodiment, it is possible to obtain linearity that is N-fold of the linearity per one resistive mixer.

As in the fifth embodiment, a point to be noted is isolation between the RF signals and the IF signals. In the lumped constant resistive mixer illustrated in FIG. 11, isolation between the RF signals and the IF signals can be achieved by an RF matching circuit 202 and an IF matching circuit 201. However, in the present embodiment, an IF distribution matching circuit constituted by the transmission lines 26-1 to 26-(2N+1) and 27-1 to 27-(N+1) and the termination resistor 28 is used, and it is therefore necessary to secure isolation by a technique different from the lumped constant resistive mixer.

Thus, in the present embodiment, the transmission lines 26-1 to 26-(2N+1), 29-1 to 29-(N+1), and 30-1 to 30-N having a length of quarter wavelength at the frequency of the RF signal are used. The transmission lines 29-1 to 29-(N+1) and 30-1 to 30-N are open stubs. Therefore, the impedance at the connection points between the IF distribution matching circuit and the transmission lines 29-1 to 29-(N+1) and 30-1 to 30-N (the connection point between the transmission line 26-(2i−1) and the transmission line 27-i, and the connection point between the transmission line 26-2k and the transmission line 27-k) is 0 (short circuit) at the frequency of the RF signal.

The transmission lines 26-1 to 26-(2N+1) rotate signal phases at the connection points between the IF distribution matching circuit and the transmission lines 29-1 to 29-(N+1) and 30-1 to 30-N, and thus the impedance seen from the drains D of the FETs 25-1 to 25-N to the IF distribution matching circuit at the frequency of the RF signal can be made infinite (opened).

For the drains D of the FETs 25-1 to 25-N, since the IF distribution matching circuit is arranged with two branches, the transmission lines 26-1 to 26-(2N+1), 29-1 to 29-(N+1), and 30-1 to 30-N are required in order to make the impedance of both branches infinite at the frequency of the RF signal.

As described above, there is about 10 times difference in frequency between the RF signals and the IF signals in the 300 GHz band, the transmission lines 26-1 to 26-(2N+1), 29-1 to 29-(N+1), and 30-1 to 30-N are sufficiently short for the IF signals. Thus, it may be considered that the transmission lines 26-1 to 26-(2N+1), 29-1 to 29-(N+1), and 30-1 to 30-N do not adversely affect the characteristics of the IF distribution matching circuit.

As described above, the present embodiment allows for securing isolation between the RF signals and the IF signals in a case where a resistive mixer is used as a unit mixer.

In the present embodiment, the amplifiers 11-1 to 11-N and 12-1 to 12-N are not essential components, and as in the first embodiment, N output terminals of the power divider 1 and input terminals of the N delay circuits 2-1 to 2-N may be connected, and output terminals of the N delay circuits 2-1 to 2-N and the gates G of the N FETs 25-1 to 25-N may be connected.

While the configuration in FIG. 12 illustrates a case where the upper side band is used as RF signals, in a case where the lower side band is used as RF signals, delay circuits 2a-1 to 2a-N may be provided instead of the delay circuits 2-1 to 2-N.

### INDUSTRIAL APPLICABILITY

The embodiments of the present invention can be applied to a mixer circuit that performs signal frequency conversion.

### REFERENCE SIGNS LIST

1, 15 Power divider
2-1 to 2-N, 2a-1 to 2a-N, 14-1 to 14-N, 14a-1 to 14a-N Delay circuit
3-1 to 3-N Unit mixer
4-1 to 4-N, 21-1 to 21-2N, 26-1 to 26-(2N+1), 27-1 to 27-(N+1) Transmission line
5, 22, 28 Termination resistor
6 Power combiner
11-1 to 11-N, 12-1 to 12-N, 13-1 to 13-N, 16-1 to 16-N, 17-1 to 17-N, 19-1 to 19-N Amplifier
18 Pre-amplifier
20-1 to 20-N, 25-1 to 25-N FET
23-1 to 23-N, 24-1 to 24-N, 29-1 to 29-(N+1), 30-1 to 30-N Transmission line

1-8. (canceled)

9. A mixer circuit comprising:
a power divider configured to divide an LO signal into N signals with equal amplitude and equal phase, N being an integer of 2 or more;
N transmission lines that are connected in series between an IF port and ground, the IF ports having an IF signal connected to an input;
N unit mixers having IF signal input terminals connected to corresponding terminations of the N transmission lines;
N delay circuits connected between N output terminals of the power divider and LO signal input terminals of the N unit mixers; and
a power combiner configured to combine, with equal amplitude and equal phase, N RF signals output from the N unit mixers,
wherein a phase delay amount of the LO signal by a k-th (k is an integer of 1 to N) delay circuit from the IF port side among the delay circuits is set to θ₁-kΔθ_{IF} or θ₁+kΔθ_{IF} (θ₁ is an optional phase), where Δθ_{IF} is a phase delay amount with respect to an IF signal of each of the N transmission lines.

10. The mixer circuit according to claim 9, further comprising:
N first amplifiers connected between the N output terminals of the power divider and input terminals of the N delay circuits; and
N second amplifiers connected between output terminals of the N delay circuits and the LO signal input terminals of the N unit mixers.

11. The mixer circuit according to claim 9, further comprising:
third amplifiers connected between RF signal output terminals of the N unit mixers and N input terminals of the power combiner.

12. A mixer circuit comprising:
a first power divider configured to divide an LO signal into N signals with equal amplitude and equal phase, N being an integer of 2 or more;
a second power divider configured to divide an RF signal into N signals with equal amplitude and equal phase;
N transmission lines that are connected in series between an IF port and ground, the IF port configured to output an IF signal;
N unit mixers with RF signal input terminals connected to corresponding N output terminals of the second power divider and IF signal output terminals connected to corresponding terminations of the N transmission lines; and
N delay circuits connected between N output terminals of the first power divider and LO signal input terminals of the N unit mixers,
wherein a phase delay amount of the LO signal by a k-th (k is an integer of 1 to N) delay circuit from the IF port side among the delay circuits is set to θ₁-(N−k+1)Δθ_{IF} or θ₁+(N−k+1)Δθ_{IF} (θ₁ is an optional phase), where Δθ_{IF} is a phase delay amount with respect to an IF signal of each of the N transmission lines.

13. The mixer circuit according to claim 12, further comprising:
N first amplifiers connected between the N output terminals of the first power divider and input terminals of the N delay circuits; and
N second amplifiers connected between output terminals of the N delay circuits and the LO signal input terminals of the N unit mixers.

14. The mixer circuit according to claim 12, further comprising:
N third amplifiers connected between the N output terminals of the second power divider and the RF signal input terminals of the N unit mixers.
transmission line with respect to an IF signal.

15. A mixer circuit comprising:
a power divider configured to divide an LO signal into N signals with equal amplitude and equal phase, N being is an integer of 2 or more;
N transistors that have sources connected to ground;
N delay circuits that are individually inserted between N output terminals of the power divider and gates of the N transistors;
a power combiner configured to combine, with equal amplitude and equal phase, N RF signals output from drains of the N transistors;
2N+1 first transmission lines that are connected in series between an IF port to which an IF signal is input and the ground, and have a length of quarter wavelength at a frequency of the RF signals;
N+1 second transmission lines, each of the N+1 second transmission lines being inserted between a termination of a (2k−1)th first transmission line from the IF port side among the first transmission lines and an input end of a 2k-th first transmission line among the first transmission lines, and between a termination of a (2N+1)th first transmission line among the first transmission lines and the ground, k being an integer of 1 to N;
N+1 third transmission lines, each of the N+1 third transmission lines having one end connected to a connection point between a (2i−1)th first transmission line from the IF port side among the first transmission lines and an i-th second transmission line among the second transmission lines, having the other end opened, and having a length of quarter wavelength at the frequency of the RF signals, i being an integer of 1 to N+1; and
N fourth transmission lines, each of the N fourth transmission lines having one end connected to a connection point between the 2k-th first transmission line from the IF port side among the first transmission lines and a k-th second transmission line among the second transmission lines, having the other end opened, and having a length of quarter wavelength at the frequency of the RF signals,
wherein a phase delay amount of the LO signal by a k-th delay circuit from the IF port side among the delay circuits is set to θ₁−kΔθ_{IF} or θ₁+kΔθ_{IF}, where Δθ_{IF} is a total phase delay amount of the (2k−1)th first transmission line, the 2k-th first transmission line, and the k-th second transmission line with respect to an IF signal.
